(19) United States
(12) Patent Application Publication
(10) Pub. No.: US 2007/0020862 A1
(43) Pub. Date: Jan. 25, 2007

(54) SEMICONDUCTOR DEVICE AND METHOD OF FABRICATING THE SAME

(75) Inventor: Dae-Won HA, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-Do (KR)

(21) Appl. No.: 11/421,171

(22) Filed: May 31, 2006

(30) Foreign Application Priority Data
Jul. 25, 2005 (KR) 2005-0067375

(51) Int. Cl. H01L 21/336

(52) U.S. Cl. 438/296

(57) ABSTRACT

In an embodiment, a semiconductor device includes a semiconductor substrate having an active region and a field region in contact with the active region. A trench isolation layer is formed within the semiconductor substrate of the field region to define the active region, and has a protrusion higher than a surface of the semiconductor substrate. A gate pattern is formed on and across the semiconductor substrate of the active region, and has a top surface disposed on substantially the same plane as a top surface of the trench isolation layer. A gate line is formed, which is self-aligned with the gate pattern to cover the gate pattern and extends over the trench isolation layer. A reduction in an effective channel length of the device due to excess trapped electrons is prevented.

### CROSS-REFERENCE TO RELATED APPLICATION

This application claims the benefit of Korean Patent Application No. 10-2005-0067375, filed on Jul. 25, 2005, the contents of which are hereby incorporated herein by reference in their entirety.

### BACKGROUND

1. Field of the Invention

The present invention relates to a semiconductor device and a method of its fabrication, and more particularly, to a semiconductor device having improved characteristics and reliability and a method of its fabrication.

2. Description of the Related Art

Highly integrated semiconductor devices often employ a trench isolation technique in their fabrication. It is well known that the trench isolation technique etches a substrate using a nitride layer as a mask to form a trench, and the trench is then filled with an insulating layer to isolate devices. In the fabrication of the semiconductor device using this, or other, conventional trench isolation technique, defects, such as a shallow pit, may occur. These defects may be due to an oxidation caused by a subsequent annealing process during which a nitride liner is not formed within the trench while an insulating layer fills the trench to form an isolation layer. Such defects may degrade the electrical characteristics of the devices, and may cause a leakage current in a PN junction region, thereby seriously affecting the isolation characteristics of the devices.

To solve the above-described problems, a technique of forming an insulating liner formed of a silicon nitride layer within a trench at the time of forming an isolation layer by a trench isolation technique has been proposed. An example is U.S. Pat. No. 5,447,884 entitled “Shallow Trench Isolation with Thin Nitride Liner” to Fahey, et al.

FIG. 1 is a layout of a conventional semiconductor device. FIGS. 2A to 2D are cross-sectional views taken along line I-I′ of FIG. 1 illustrating a method of fabricating the conventional semiconductor device.

Referring to FIGS. 1 and 2A, a semiconductor substrate 1 such as a silicon substrate is prepared, which has an active region A where devices are to be formed, and a field region F where an isolation layer for isolating the devices is to be formed. A pad oxide layer 5 and a pad nitride layer 10 are sequentially stacked on the semiconductor substrate of the active region A to expose the semiconductor substrate in the field region F. The pad oxide layer 5 is formed of a thermal oxide layer, and the pad nitride layer 10 is formed of a silicon nitride layer. The exposed semiconductor substrate 1 in the field region F is etched using the pad nitride layer 10 as an etch mask to form a trench 15.

Referring to FIGS. 1 and 2B, the substrate having the trench 15 is thermally oxidized to form a buffer oxide layer 20 on an inner wall of the trench 15. Subsequently, a conformal insulating liner 25 is formed on the entire surface of the substrate having the buffer oxide layer 20. The insulating liner 25 is formed of a silicon nitride layer. The buffer oxide layer 20 serves to cure any damage caused by substrate etching during the forming of the trench 15, and prevents stress and a trap center from occurring between the buffer oxide layer 20 and the insulating liner 25 formed of the nitride layer. In particular, preventing the internal oxidation of the trench 15 from occurring by means of the insulating liner 25 formed of the silicon nitride layer causes an electrical charge to be trapped within the insulating liner 25 or at an interface between the insulating liner 25 and the buffer oxide layer 20. This causes the electrical charge, having a polarity, to couple with an electrical charge on a sidewall of the trench 15 having an opposite polarity. Accordingly, the buffer oxide layer 20 should be formed relatively thick to suppress the electrical charge from being trapped within the insulating liner 25 or at the interface between the insulating liner 25 and the buffer oxide layer 20. Thus, there is a difficulty in reducing the thickness of the buffer oxide layer 20 for when the devices are highly integrated.

Subsequently, a preliminary trench isolation layer 30 that fills the trench 15 is formed on the substrate having the insulating liner 25.

The preliminary trench isolation layer 30 is then planarized using a chemical mechanical polishing (CMP) technique until a top surface of the pad nitride layer 10 is exposed, as shown in FIG. 2C. As a result, a trench isolation layer 30a is formed while an insulating liner pattern 25a is also formed.

Referring to FIGS. 1 and 2D, the exposed pad nitride layer 10 is removed by a chemical solution containing a phosphoric acid solution to expose a top surface of the pad oxide layer 5. Subsequently, the pad oxide layer 5 is removed by a chemical solution containing a hydrofluoric acid solution to expose the semiconductor substrate of the active region A. In this case, while the pad nitride layer 10 is removed, the insulating liner pattern 25a may be over-etched to form a depressed region or, in other words, a recessed region adjacent to an upper edge of the trench 15. In addition, while the pad oxide layer 5 is removed, a top surface of the trench isolation layer 30a may be inadvertently lowered, as shown in FIG. 2D.

Subsequently, a gate oxide layer 35 is formed on the semiconductor substrate of the active region A. A gate electrode 40 that crosses over the active region A and extends over the trench isolation layer 30a is then formed on the substrate having the gate oxide layer 35. Subsequently, a source region S and a drain region D are formed within the semiconductor substrate of the active region A at both sides of the gate electrode 40. As a result, the gate electrode 40, the gate oxide layer 35, the source region S, and the drain region D, may constitute a metal oxide semiconductor (MOS) transistor.

Hereinafter, a description will be given assuming that the MOS transistor is a p-channel MOS (PMOS) transistor.

When an operating voltage greater than a threshold voltage is applied to the gate electrode 40 and an electrical potential difference is applied between the source region S and the drain region D, an electron-hole pair is generated within a channel region C (FIG. 1) near the drain region D due to impact ionization. In addition, the impact ionization becomes severe due to a field crowding effect at both edges of the channel region C adjacent to the trench isolation layer 30a and positioned below the gate electrode 40.

In this case, generated holes flow to the drain region D due to the electrical potential difference between the source region S and the drain region D. In contrast, some of the electrons generated by the impact ionization are trapped within the trench isolation layer 30a. That is, electron trap regions 45b exist within the trench isolation layer 30a near both edges of the channel region C. In particular, it is well known that the electrons are apt to be easily trapped at the interface between the insulating liner pattern 25a formed of a silicon nitride layer and the buffer oxide layer 20 formed of a silicon oxide layer. As shown in FIG. 1, the gate electrode 40 covers both edges of the channel region C positioned below the gate electrode 40 while extending over the trench isolation layer 30a. However, a recessed region may be formed in an upper edge region of the trench isolation layer 30a adjacent to the channel region C. As a result, the gate electrode 40 may cover the recessed region of the trench isolation layer 30a while extending over the trench isolation layer 30a. Accordingly, a strong electric field E may occur between the active region A and the gate electrode 40 of the recessed region of the trench isolation layer 30a. As a result, many electrons may be trapped within the insulating liner pattern 25a or at an interface between the insulating liner pattern 25a and the buffer oxide layer 20, forming the electron trap regions 45b. As such, when the number of electrons trapped within the electron trap regions 45b increases, holes are collected in both edges of the channel region C. The holes serve as extension regions 45a of the drain region D. Consequently, an effective channel length at both edges of the channel region C adjacent to the trench isolation layer 30a is reduced due to the extension regions 45a. That is, the channel region C has a first channel length L1 prior to the formation of the extension regions 45a, but has a second effective channel length L2 shorter than the first channel length L1 due to the extension regions 45a. The reduction in channel length causes problems well-known in the art, such as punch-through. Consequently, both edges of the channel region C adjacent to the trench isolation layer 30a are vulnerable to hot electron induced punch-through (HEIP).

In addition, due to the recessed region formed in the upper edge region of the trench isolation layer 30a, the electric field E may be concentrated on the upper edge region of the channel region C adjacent to the trench isolation layer 30a to cause a parasitic current. Accordingly, the threshold voltage may decrease in the upper edge region of the channel region C adjacent to the trench isolation layer 30a. That is, an inverse narrow-width effect may occur.

To prevent many electrons from being trapped within the insulating liner pattern 25a, or at the interface between the insulating liner pattern 25a and the buffer oxide layer 20, the buffer oxide layer 20 should be formed relatively thick. Reducing this thickness for highly integrated devices is then problematic. Accordingly, the buffer oxide layer 20 is typically kept at an almost constant thickness, e.g. about 60 Å, in the semiconductor device employing the insulating liner pattern 25a regardless of the level of the semiconductor device integration.

Furthermore, when the trench is formed within the semiconductor substrate of the field region F to define the active region A to form the trench isolation layer, the active region A is formed to a first width W1. After the thick buffer oxide layer 20 is formed, the active region A is formed to a second width W2 smaller than the first width W1. As a result, a channel width of the channel region C may have the second width W2. Accordingly, the reduction in channel width causes the drive current to decrease.

Also, with high device integration, the active region A may need to be designed to be spaced from another active region adjacent to the active region A by a required minimum distance due to photolithography and etching processes. However, when the buffer oxide layer 20 is formed thickly, as described above, problems may occur in forming the trench isolation layer 30a between the active region A and the other active region. That is, an upper width of the trench 15 may be reduced due to the thick buffer oxide layer 20, which may cause difficulty in filling the trench 15 with an insulating layer. In addition, the dimension of the active region A may decrease to degrade the MOS transistor reliability.

Accordingly, a new semiconductor device structure and a method of fabrication to solve the above-described problems are required.

### SUMMARY

Embodiments provide semiconductor devices having improved characteristics and reliability and a method of their fabrication.

In one aspect, embodiments are directed to a semiconductor device having improved characteristics and reliability. The semiconductor device may include a semiconductor substrate having an active region and a field region in contact with the active region. A trench isolation layer may be disposed in the semiconductor substrate of the field region to define the active region, and to protrude higher than a surface of the active region. An insulating liner pattern may be interposed between the trench isolation layer and the semiconductor substrate to cover sidewalls of the protrusion of the trench isolation layer. A gate pattern may be disposed on and across the semiconductor substrate of the active region to have a top surface disposed on substantially the same horizontal line as a top surface of the trench isolation layer. A gate line may be self-aligned with the gate pattern, covering the gate pattern, and extending over the trench isolation layer.

In some embodiments, a buffer insulating pattern may be further interposed between the insulating liner pattern and the semiconductor substrate. Further, the buffer insulating pattern may be extended to interpose at least between the insulating liner pattern and the gate pattern. The buffer insulating pattern may comprise a silicon oxide layer.

In other embodiments, the insulating liner pattern may comprise a silicon nitride layer.

In still other embodiments, the gate pattern may comprise a gate dielectric layer pattern and a gate conductive layer pattern, which are sequentially stacked.

In yet other embodiments, sidewalls of the gate pattern adjacent to the trench isolation layer may be substantially self-aligned with edges of the active region.

In another aspect, embodiments are directed to a method of fabricating a semiconductor device having improved characteristics and reliability. The method may include preparing a semiconductor substrate having an active region and a field region in contact with the active region. A gate layer may be formed to cover the semiconductor substrate of the active region. The semiconductor substrate of the field region may be etched using the gate layer as a mask to form a trench. A trench isolation layer may be formed within the semiconductor substrate of the field region to fill the trench and to protrude higher than a surface of the active region. Meanwhile, an insulating liner pattern may be formed to cover a sidewall and a bottom surface of the trench isolation layer, wherein the trench isolation layer has a top surface disposed on substantially the same horizontal line as a top surface of the gate layer. A gate line may be formed on the substrate having the trench isolation layer, which crosses over the gate layer and extends over the trench isolation layer. The gate layer may be etched using the gate line as a mask to form a gate pattern self-aligned with the gate line on the semiconductor substrate of the active region.

In some embodiments, the gate layer may comprise a gate dielectric layer and a gate conductive layer, which are sequentially stacked.

In other embodiments, forming the trench isolation layer while forming the insulating liner pattern may include forming an insulating liner conformally covering the trench and the gate layer on the semiconductor substrate having the trench, forming a preliminary trench isolation layer filling the trench on the semiconductor substrate having the insulating liner, the preliminary trench isolation layer having a top surface higher than the top surface of the gate layer, and planarizing the preliminary trench isolation layer to expose the top surface of the gate layer while selectively removing the insulating liner formed over the gate layer. Prior to the formation of the insulating liner, the method may further include forming a buffer insulating layer on an inner wall of the trench. Further, the method may comprise forming the buffer insulating layer on an exposed surface of the gate layer as well as the inner wall of the trench. The buffer insulating layer may comprise a silicon oxide layer.

In still other embodiments, the insulating liner may comprise a silicon nitride layer.

Still other embodiments are directed to a method of fabricating a semiconductor device. The method includes preparing a semiconductor substrate having an active region and a field region in contact with the active region. A gate layer may be formed to cover the semiconductor substrate of the active region. The semiconductor substrate of the field region may be anisotropically etched using the gate layer as an etch mask to form a trench. A buffer insulating layer may be formed on an inner wall of the trench. A conformal insulating liner may be formed on the entire surface of the substrate having the trench using a deposition method. A preliminary trench isolation layer may be formed on the substrate having the insulating liner to fill the trench, and the preliminary trench isolation layer may have a top surface higher than a top surface of the gate layer. The preliminary trench isolation layer may be planarized to expose the top surface of the gate layer to form a trench isolation layer having a top surface disposed on substantially the same horizontal line as the top surface of the gate layer, while forming an insulating liner pattern remaining to cover a sidewall and a bottom surface of the trench isolation layer, and a buffer insulating pattern remaining on the inner wall of the trench. A gate line may be formed to cross over the gate layer and extend over the trench isolation layer on the semiconductor substrate having the trench isolation layer. The gate layer may be etched using the gate line as a mask to form a gate pattern self-aligned with the gate line on the semiconductor substrate of the active region.

In some embodiments, the gate layer may comprise a gate dielectric layer and a gate conductive layer, which are sequentially stacked. The gate conductive layer may comprise a polysilicon layer.

In still other embodiments, the method may comprise forming the buffer insulating layer on an exposed surface of the gate layer as well as the inner wall of the trench.

In yet other embodiments, the insulating liner may comprise a silicon nitride layer.

In another embodiment, the gate line may comprise a polysilicon layer, a metal layer, or a metal silicide layer.

### BRIEF DESCRIPTION OF THE DRAWINGS

The foregoing and other objects, features and advantages of the invention will be apparent from the more particular description of embodiments, as illustrated in the accompanying drawings. The drawings are not necessarily to scale, emphasis instead being placed upon illustrating the principles of the embodiments.

FIG. 1 is a layout of a conventional semiconductor device.

FIGS. 2A to 2D are cross-sectional views taken along line I-I′ of FIG. 1 illustrating the conventional semiconductor device.

FIG. 3 is a layout of a semiconductor device according to some embodiments.

FIGS. 4A, 5A, 6A, and 7A are cross-sectional views taken along line II-II′ of FIG. 3.

FIGS. 4B, 5B, 6B, and 7B are cross-sectional views taken along line III-III′ of FIG. 3.

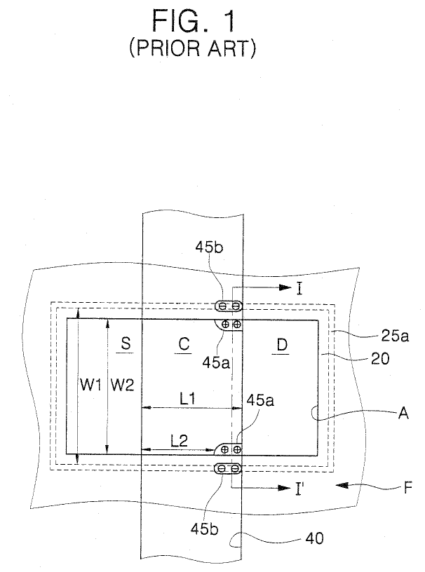

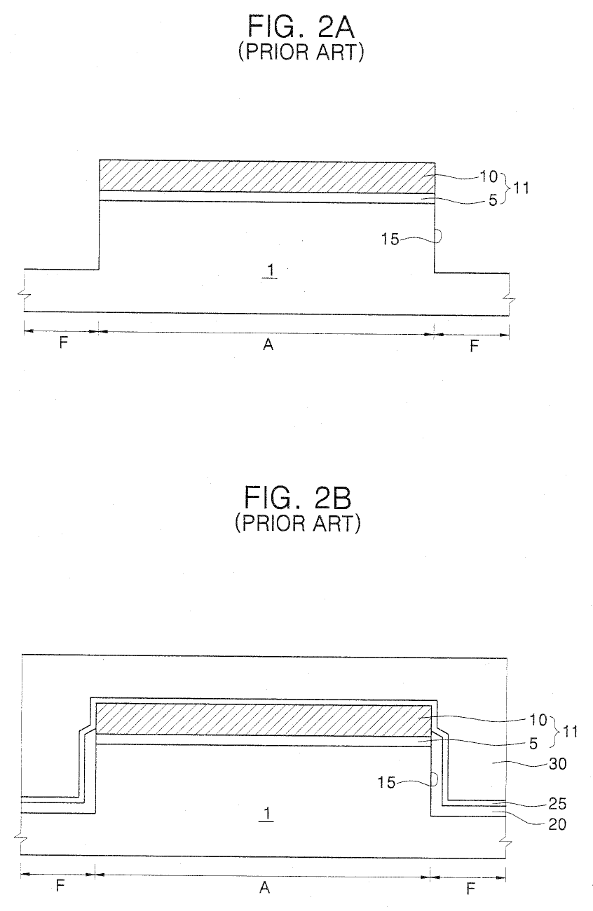

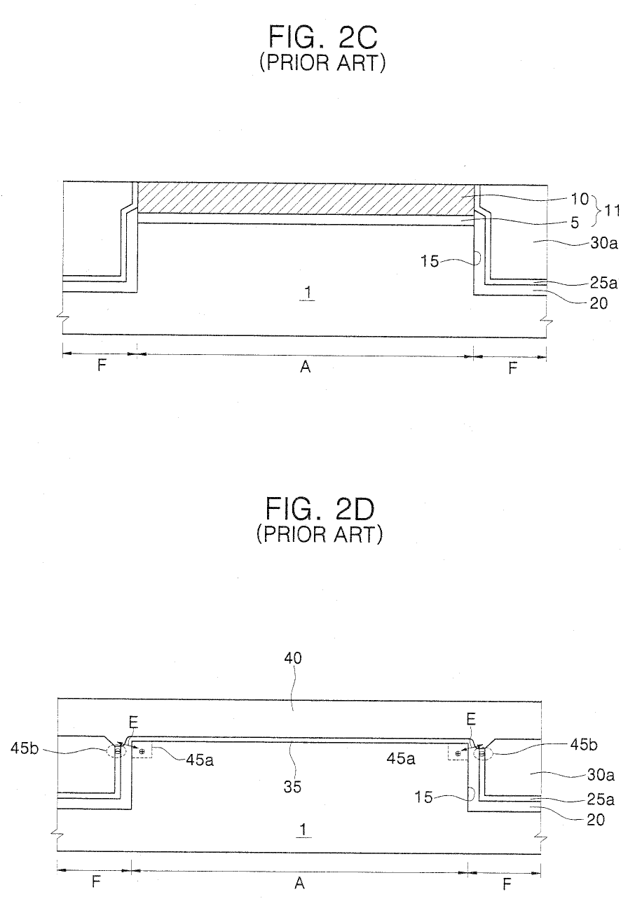

### DETAILED DESCRIPTION

Embodiments of the present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout the specification.

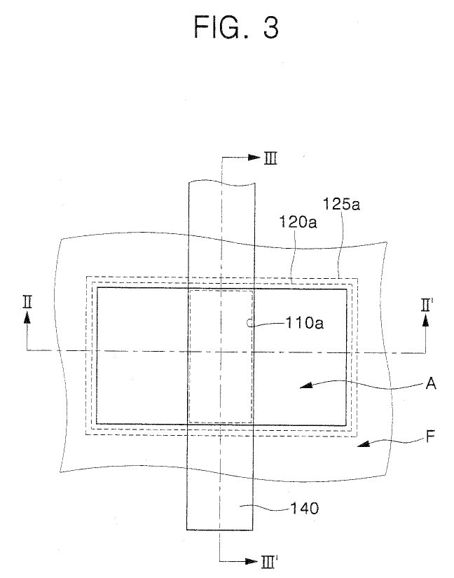

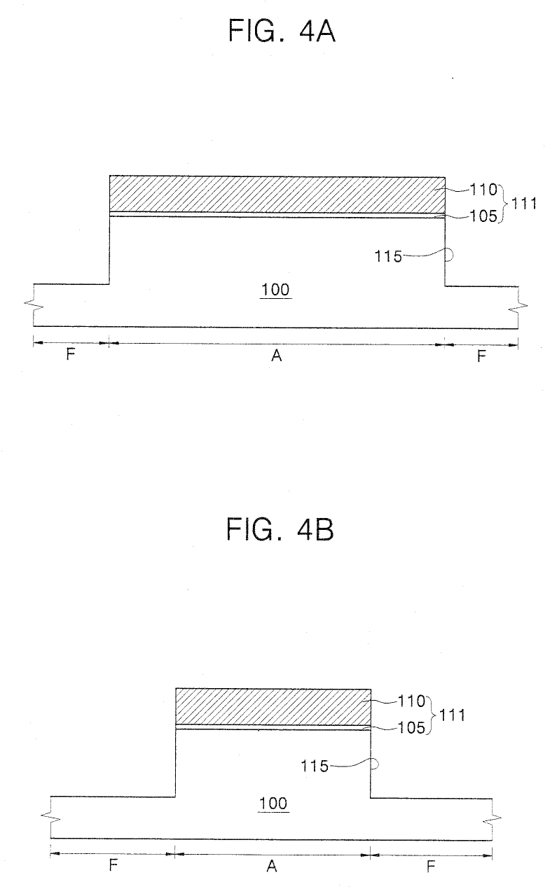

FIG. 3 is a layout of a semiconductor device according to some embodiments of the present invention. FIGS. 4A, 5A, 6A, and 7A are cross-sectional views taken along line II-II′ of FIG. 3, and FIGS. 4B, 5B, 6B, and 7B are cross-sectional views taken along line III-III′ of FIG. 3.

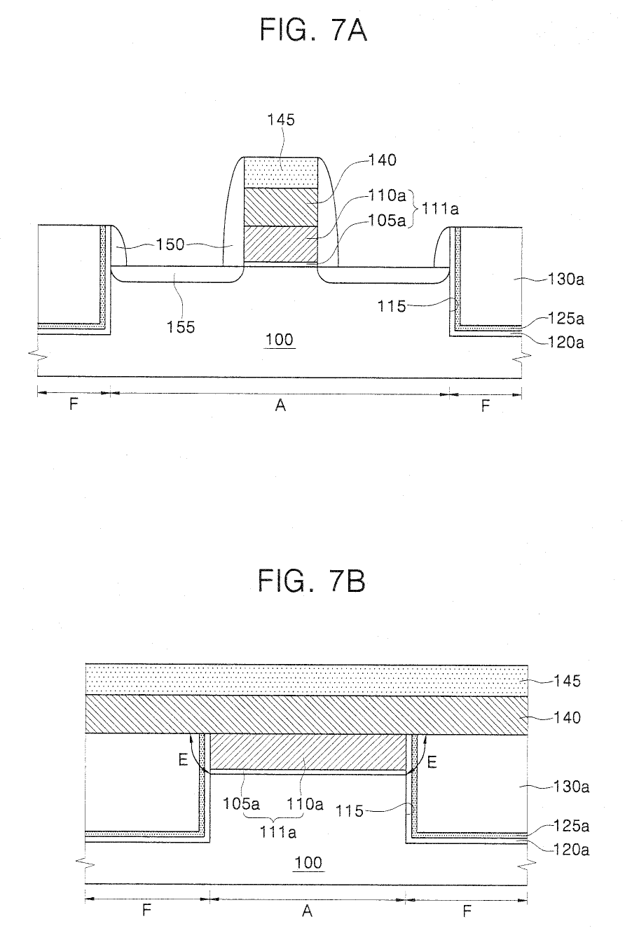

First, a semiconductor device will now be described with reference to FIGS. 3, 7A, and 7B.

The semiconductor device of this embodiment includes a semiconductor substrate 100 having an active region A defined by a field region F. The semiconductor substrate 100 may be a single crystalline silicon substrate. Alternatively, the substrate 100 can be formed of a material such as Ge, SiGe, GaP, GaAs, SiC, SiGeC, InAs, InPA or combinations thereof. Alternatively, the substrate 100 may be a silicon-on-insulator (SOI) substrate. The semiconductor substrate 100 of the active region A may be a substrate having an N-well or a P-well.

A trench isolation layer 130a is disposed in the semiconductor substrate 100 of the field region F to define the active region A. The trench isolation layer 130a is protruded higher than a surface of the active region A. The trench isolation layer 130a may comprise silicon oxide.

A gate pattern 111a is disposed over the semiconductor substrate 100 of the active region A. In this case, the gate pattern 111a has a top surface disposed on substantially the same plane or horizontal line as a top surface of the trench isolation layer 130a. The gate pattern 111a may comprise a gate dielectric layer pattern 105a and a gate conductive layer pattern 110a, which are sequentially stacked. The gate dielectric layer pattern 105a may comprise a silicon oxide or high-k dielectric. The gate conductive layer pattern 110a may comprise polysilicon. In this case, sidewalls of the gate conductive layer pattern 10a adjacent to the trench isolation layer 130a may be self-aligned with edges of the active region A.

An insulating liner pattern 125a may be interposed between the trench isolation layer 130a and the semiconductor substrate 100 to cover a sidewall of the protruded trench isolation layer 130a. The insulating liner pattern 125a may comprise silicon nitride.

A buffer insulating pattern 120a is interposed between the insulating liner pattern 125a and the semiconductor substrate 100. The buffer insulating pattern 120a may comprise silicon oxide. For example, the buffer insulating pattern 120a may comprise thermal oxide. Further, the buffer insulating pattern 120a may be interposed at least between the gate pattern 111a and the insulating liner pattern 125a.

A gate line 140 may be self-aligned with the gate pattern 111a to cover the gate pattern 111a and extend over the trench isolation layer 130a. The gate line 140 may comprise a polysilicon layer, a metal layer, or a metal silicide layer.

An insulating spacer 150 may be disposed to not only cover sidewalls of the gate line 140, but also sidewalls of the gate pattern 111a. Further, the insulating spacer 150 may cover sidewalls of the protruded trench isolation layer 130a. The insulating spacer 150 may comprise a silicon oxide layer or a silicon nitride layer.

Impurity regions 155 may be disposed in the semiconductor substrate of the active region A divided by the gate pattern 111a.

As a result, the gate dielectric layer pattern 105a, the gate conductive layer pattern 110a, the gate line 140, and the impurity regions 155, which are disposed in the semiconductor substrate of the active region A, may constitute a MOS transistor. In this case, the gate conductive layer pattern 110a and the gate line 140 may be defined as a gate electrode of the MOS transistor. In addition, the impurity regions 155 may be defined as source and drain regions of the MOS transistor.

According to the presently described embodiment, the trench isolation layer 130a is protruded higher than a surface of the active region A. In addition, as already described, the gate conductive layer pattern 110a constituting the gate electrode may have a top surface disposed on substantially the same plane or horizontal line as the top surface of the trench isolation layer 130a while sidewalls of the gate conductive layer pattern 110a adjacent to the trench isolation layer 130a may be substantially self-aligned with the edges of the active region A. Accordingly, the gate conductive layer pattern 110a may be disposed only in the active region A, so that there is a reduced probability that electrical charges are trapped within the insulating liner pattern 125a or at the interface between the insulating liner pattern 125a and the buffer insulating pattern 120a. These trapped electrical charges may be due to an electric field generated between the gate conductive layer pattern 110a constituting the gate electrode and the semiconductor substrate of the active region A. In addition, a distance between the semiconductor substrate of the active region A and the gate line 140 disposed above the semiconductor substrate of the active region A is greater than that of the related art. As a result, only a weak electric field E may occur between the semiconductor substrate of the active region A and the gate line 140 disposed above the semiconductor substrate of the active region A. As a result, minimal electrical charge may be trapped within the insulating liner pattern 125a or at the interface between the insulating liner pattern 125a and the buffer insulating pattern 120a from the semiconductor substrate of the active region A.

In particular, when the MOS transistor is a PMOS transistor, electrons may be suppressed from being trapped within the insulating liner pattern 125a or at the interface between the insulating liner pattern 125a and the buffer insulating pattern 120a from the semiconductor substrate of the active region A. As a result, degradation of the device caused by HEIP may be suppressed, so that the reliability of the device may be enhanced.

In addition, the gate conductive layer pattern 10a of the gate electrode has a top surface disposed on substantially the same plane or horizontal line as the top surface of the trench isolation layer 130a while sidewalls of the gate conductive layer pattern 110a adjacent to the trench isolation layer 130a are substantially self-aligned with the edges of the active region A, so that a parasitic current may be suppressed from occurring in the edge region of the active region A disposed below the gate conductive layer pattern 110a and adjacent to the trench isolation layer 130a. That is, a decrease of the threshold voltage which may occur in the edge region of the active region A disposed below the gate conductive layer pattern 110a and adjacent to the trench isolation layer 130a, may be prevented.

In addition, the buffer insulating pattern 120a need not be relatively thick to suppress trapped electrical charges, as in the related art. Thus, the high integration of the semiconductor device may be more readily implemented.

As described above, according to the semiconductor device of the embodiments, the electrical charges may be suppressed from being trapped within the insulating liner pattern 125a or at the interface between the insulating liner pattern 125a and the buffer insulating pattern 120a, to improve the characteristics and the reliability of the semiconductor device.

Hereinafter, a method of fabricating the semiconductor device will be described for implementing the semiconductor device having the enhanced characteristics and reliability.

The method of fabricating the semiconductor device according to embodiments of the present invention will now be described with reference to FIGS. 3, 4A, 4B, 5A, 5B, 6A, 6B, 7A, and 7B.

Referring to FIGS. 3, 4A, and 4B, a semiconductor substrate 100 having an active region A and a field region F in contact with the active region A is prepared. The semiconductor substrate 100 of the active region A may be a semiconductor substrate where an N-well or P-well is formed by implanting ions. A gate layer 111 covering the semiconductor substrate 100 of the active region A is formed to expose the semiconductor substrate of the field region F. The gate layer 111 may comprise a gate dielectric layer 105 and a gate conductive layer 110, sequentially stacked. Forming the gate layer 111 may include sequentially stacking a dielectric layer and a conductive layer on the entire surface of the semiconductor substrate 100, and patterning the conductive layer and the dielectric layer using typical photolithography and etching processes. In this case, a hard mask layer such as a silicon nitride layer or a silicon oxide layer, or a photoresist mask may be used as a mask for patterning the conductive layer and the dielectric layer.

The gate dielectric layer 105 may be formed of a silicon oxide layer or a high-k dielectric layer. The gate conductive layer 110 may be formed of a silicon layer. For example, the gate conductive layer 110 may be formed of a polysilicon layer.

The exposed semiconductor substrate of the field region F is selectively etched to form a trench 115. Etching the semiconductor substrate of the field region F may be performed by an anisotropic etching process. The anisotropic etching process may be a dry etching process.

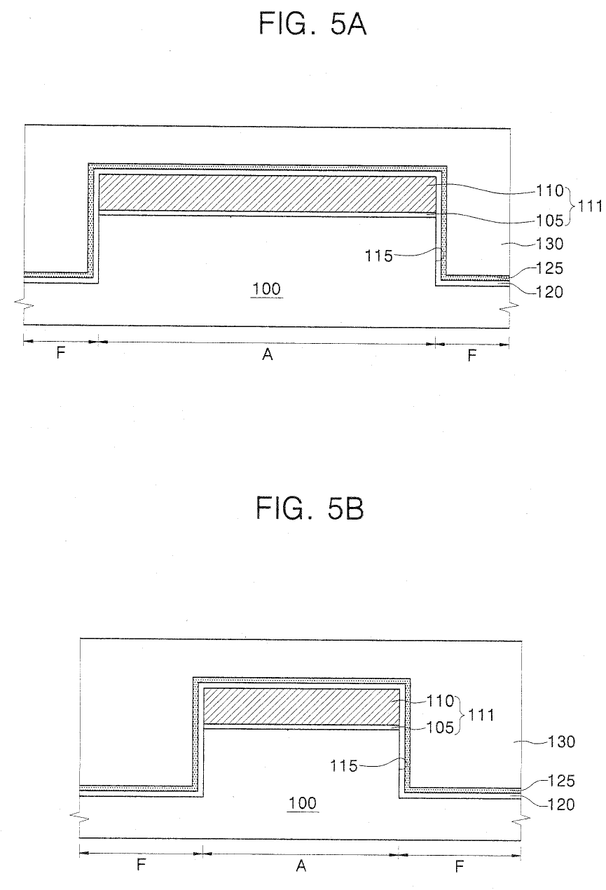

Referring to FIGS. 3, 5A, and 5B, a buffer insulating layer 120 may be formed on an inner wall of the trench 115. The buffer insulating layer 120 may be formed of a silicon oxide layer. In particular, the buffer insulating layer 120 may be formed by thermally oxidizing the substrate having the trench 115, for example.

When the gate conductive layer 110 is formed of a polysilicon layer, the buffer insulating layer 120 may be formed on the exposed surfaces of the polysilicon layer as well as the inner wall of the trench 115. The buffer insulating layer 120 may cure any etch damage applied to the semiconductor substrate 100 while the anisotropic etching process is performed to form the trench 115.

An insulating liner 125 is formed on the substrate having the buffer insulating layer 120. The insulating liner 125 may be formed of an insulating layer by a deposition method. For example, the insulating liner 125 may be formed of a silicon nitride layer by a chemical vapor deposition (CVD) method. The insulating liner 125 may prevent the semiconductor substrate on the inner wall of the trench 115 from being oxidized due to subsequent annealing processes for forming the semiconductor device. In addition, a decreased area of the active region A due to the oxidation caused by the following annealing process may be minimized.

A preliminary trench isolation layer 130 may be formed on the entire surface of the substrate having the insulating liner 125. In this case, the preliminary trench isolation layer 130 may have a top surface higher than a top surface of the gate layer 111. The preliminary trench isolation layer 130 may be formed of a silicon oxide layer.

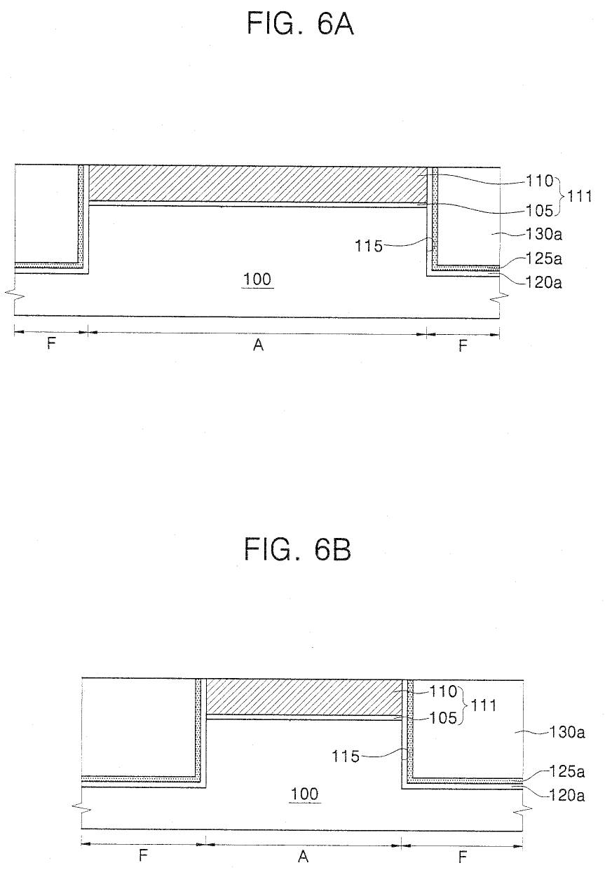

Referring to FIGS. 3, 6A, and 6B, a trench isolation layer 130a is formed within the semiconductor substrate of the field region F, protruding higher than a surface of the active region A. In this case, the trench isolation layer 130a has a top surface disposed on substantially the same plane as the top surface of the gate conductive layer 110. Specifically, the preliminary trench isolation layer 130 is planarized until the top surface of the gate conductive layer 110 is exposed so that the trench isolation layer 130a is formed. Planarizing the preliminary trench isolation layer 130 may be performed by a CMP process. In addition, the buffer insulating layer 120 and the insulating liner 125 formed on the gate conductive layer 110 may be selectively removed by the process of exposing the top surface of the gate conductive layer 110, so that a buffer insulating pattern 120a and an insulating liner pattern 125a may remain to surround a sidewall and a bottom surface of the trench isolation layer 130. That is, the buffer insulating pattern 120a and the insulating liner pattern 125a may be interposed between the trench isolation layer 130a and the gate conductive layer 110 as well as between the trench isolation layer 130a and the semiconductor substrate 100.

Referring to FIGS. 3, 7A, and 7B, a gate line 140 is formed on the substrate having the trench isolation layer 130, which crosses over the gate layer 111 and extends over the trench isolation layer 130. The gate line 140 may be formed of a conductive layer. For example, the gate line 140 may be formed of a polysilicon layer, a metal layer, or a metal silicide layer. The formation of the gate line 140 may be performed by typical photolithography and etching processes. A hard mask layer pattern 145 may be used as an etch mask in the etching process for forming the gate line 140. The hard mask layer pattern 145 may be formed of a silicon nitride layer.

The gate layer 111 is etched using the gate line 140 as a mask to form a gate pattern 111a self-aligned with the gate line 140 on the semiconductor substrate of the active region A. As a result, the gate pattern 111a has a top surface crossing the semiconductor substrate of the active region A and disposed on substantially the same plane or horizontal line as the top surface of the trench isolation layer 130a.

Subsequently, an insulating spacer 150 may be formed to cover the exposed sidewall of the protrusion of the trench isolation layer 130a as well as the exposed sidewalls of the gate pattern 111a and the gate line 140. The insulating spacer 150 may be formed of a silicon nitride layer or a silicon oxide layer. Impurity ions may be implanted into the semiconductor substrate of the active region A using the gate line 140 and the trench isolation layer 130a as ion implantation masks to form impurity regions 155, i.e. source and drain regions. As a result, the gate conductive layer pattern 10a, the gate line 140, the gate dielectric layer pattern 105a, and the impurity regions 155 may constitute a MOS transistor.

According to the embodiments described above, trapped electrical charges may be suppressed within the insulating liner pattern 125a or at the interface between the insulating liner pattern 125a and the buffer insulating pattern 120a, so that the characteristics and reliability of the device may be enhanced. In particular, when the MOS transistor comprising the gate conductive layer pattern 110a, the gate line 140, the gate dielectric layer pattern 105a, and the impurity regions 155 is a PMOS transistor, trapped electrons may be suppressed within the insulating liner pattern 125a or at the interface between the insulating liner pattern 125a and the buffer insulating pattern 120a from the semiconductor substrate of the active region A. As a result, characteristic degradation of the device due to HEIP, for example, may be suppressed, so that device reliability may be enhanced.

Preferred embodiments have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a semiconductor substrate having an active region defined by a field region;
a trench isolation layer disposed in the field region, the trench isolation layer protruding higher than a surface of the active region;
a gate pattern disposed on the active region and having a top surface at substantially a same plane as a top surface of the trench isolation layer; and
a gate line overlying the gate pattern, and extending over the trench isolation layer.

2. The semiconductor device of claim 1, further comprising an insulating liner pattern interposed between the trench isolation layer and the semiconductor substrate and covering sidewalls of the protruded trench isolation layer.

3. The semiconductor device according to claim 2, further comprising:
a buffer insulating pattern interposed between the insulating liner pattern and the semiconductor substrate.

4. The semiconductor device according to claim 3, wherein the buffer insulating pattern is interposed between the insulating liner pattern and the gate pattern.

5. The semiconductor device according to claim 3, wherein the buffer insulating pattern comprises silicon oxide.

6. The semiconductor device according to claim 1, wherein the insulating liner pattern comprises silicon nitride.

7. The semiconductor device according to claim 1, wherein the gate pattern comprises a gate dielectric layer pattern and a gate conductive layer pattern.

8. The semiconductor device according to claim 1, wherein sidewalls of the gate pattern adjacent to the trench isolation layer are self-aligned with edges of the active region.

9. The semiconductor device according to claim 1, further comprising insulating spacers disposed on sidewalls of the protruded trench isolation layer.

10. A method of fabricating a semiconductor device, comprising:
preparing a semiconductor substrate having an active region defined by a field region;
forming a gate layer covering the active region;
etching the semiconductor substrate in the field region, using the gate layer as a mask to form an isolation trench;
forming a trench isolation layer to fill the isolation trench, the trench isolation layer protruding higher than the active region, the trench isolation layer having a top surface disposed on substantially the same plane as a top surface of the gate layer;
forming a gate line on the gate layer and on the trench isolation layer; and
etching the gate layer, using the gate line as a mask, and forming a gate pattern self-aligned with the gate line on the active region.

11. The method according to claim 10, wherein the gate layer includes a gate dielectric layer and a gate conductive layer, which are sequentially stacked.

12. The method of claim 10, which further comprises forming an insulating liner conformally covering a sidewall and a bottom surface of the trench.

13. The method according to claim 12, wherein forming the trench isolation layer comprises:
forming a preliminary trench isolation layer filling the trench on the semiconductor substrate having the insulating liner, the preliminary trench isolation layer having a top surface higher than the top surface of the gate layer; and
planarizing the preliminary trench isolation layer to expose the top surface of the gate layer while selectively removing the insulating liner formed over the gate layer.

14. The method according to claim 12, further comprising:
before forming the insulating liner, forming a buffer insulating layer on an inner wall of the trench.

15. The method according to claim 14, wherein the buffer insulating layer is formed on an exposed surface of the gate layer as well as the inner wall of the trench.

16. The method according to claim 14, wherein the buffer insulating layer comprises silicon oxide.

17. The method according to claim 12, wherein the insulating liner comprises silicon nitride.

18. A method of fabricating a semiconductor device, comprising:
preparing a semiconductor substrate having an active region defined by a field region;
forming a gate layer covering the active region;
anisotropically etching the semiconductor substrate in the field region, using the gate layer as an etch mask to form an isolation trench;
forming a buffer insulating layer on an inner wall of the trench;
forming an insulating liner on a surface of the semiconductor substrate having the trench;
forming a preliminary trench isolation layer to fill the trench, the preliminary trench isolation layer having a top surface higher than a top surface of the gate layer;
planarizing the preliminary trench isolation layer to expose the top surface of the gate layer and forming a trench isolation layer having a top surface disposed on substantially a same plane as the top surface of the gate layer, while forming an insulating liner pattern to cover a sidewall and a bottom surface of the trench isolation layer, and forming a buffer insulating pattern on the inner wall of the trench;
forming a gate line on the gate layer and the trench isolation layer; and
etching the gate layer using the gate line as a mask to form a gate pattern self-aligned with the gate line on the semiconductor substrate of the active region.

19. The method according to claim 18, wherein the gate layer comprises a gate dielectric layer and a gate conductive layer.

20. The method according to claim 19, wherein the gate conductive layer comprises polysilicon.

21. The method according to claim 18, wherein the buffer insulating layer is formed on an exposed surface of the gate layer as well as the inner wall of the trench.

22. The method according to claim 18, wherein the insulating liner comprises silicon nitride.

23. The method according to claim 18, wherein the gate line comprises a polysilicon layer, a metal layer, or a metal silicide layer.
